(19) United States
(12) Patent Application Publication
(10) Pub. No.: US 2014/0187051 A1
(43) Pub. Date: Jul. 3, 2014

(54) Poly Removal for replacement gate with an APM mixture

(71) Applicant: Intermolecular Inc., (US)

(72) Inventors: Joanna Wasyluk, Dresden (DE); Paul Besser, Sunnyvale, CA (US); Stephen Kronholz, Dresden (DE); Gregory Nowling, San Jose, CA (US); James Schaeffer, Dresden (DE)

(73) Assignee: INTERMOLECULAR INC., San Jose, CA (US)

(21) Appl. No.: 13/727,818

(22) Filed: Dec. 27, 2012

(51) Int. Cl. H01L 21/306

(52) U.S. Cl. CPC H01L 21/30604
USPC 438/745; 510/175

(57) ABSTRACT

A method for removing poly-silicon dummy gate structures using an ammonium hydroxide-hydrogen peroxide-water (APM) solution with concentrations between 1:10:20 and 1:1:2 and at temperatures between 20 C and 80 C for times between 1 minute and 60 minutes.

### TECHNICAL FIELD

The present disclosure relates generally to methods for forming semiconductor devices using wet etch technologies.

### BACKGROUND

Advanced semiconductor devices continue to shrink in size. This increases the density and performance of the devices. Additional benefits of increased manufacturing efficiency and lower costs are also realized. As the size of the devices shrink, the processing sequences become more challenging.

One of the critical elements of the semiconductor devices is the gate structure. The design, materials, size, and process sequence details of the gate structure determine attributes such as power consumption, speed, and reliability. As the size of the semiconductor devices has continued to shrink, the gate dielectric material has changed from silicon dioxide to high k dielectric material such as hafnium oxide and the like. Additionally, the conductive materials used as gate electrodes have been selected to have the proper work function for n-type and p-type devices.

Traditionally, the manufacturing of semiconductor devices has employed a “gate first” manufacturing process sequence wherein the gate structure is formed and the remaining elements are formed subsequent to the gate structure formation. The gate structure can be damaged during some of the subsequent processing steps and this has limited the process window (e.g. temperature) of some of the subsequent processing steps. An alternate manufacturing process sequence known as “gate last” or “replacement gate” forms the gate structure and the surrounding elements using a “dummy gate” that is used as a structural surrogate for the gate during the manufacturing process. The dummy gate structure is then removed and the final gate materials are deposited. This allows a broader process window during the manufacturing and does not expose the final gate materials to potential damage during the processing. The removal of the dummy gate structure is a critical step in this manufacturing process sequence.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, poly-silicon structures are removed using an ammonium hydroxide-hydrogen peroxide-water (APM) mixture with concentrations between 1:10:20 and 1:1:2 and at temperatures between 20 C and 80 C for times between 1 minute and 60 minutes.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 presents a flow chart describing methods according to some embodiments.

FIG. 2 illustrates a simple device schematic according to some embodiments.

FIG. 3 illustrates a simple device schematic according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

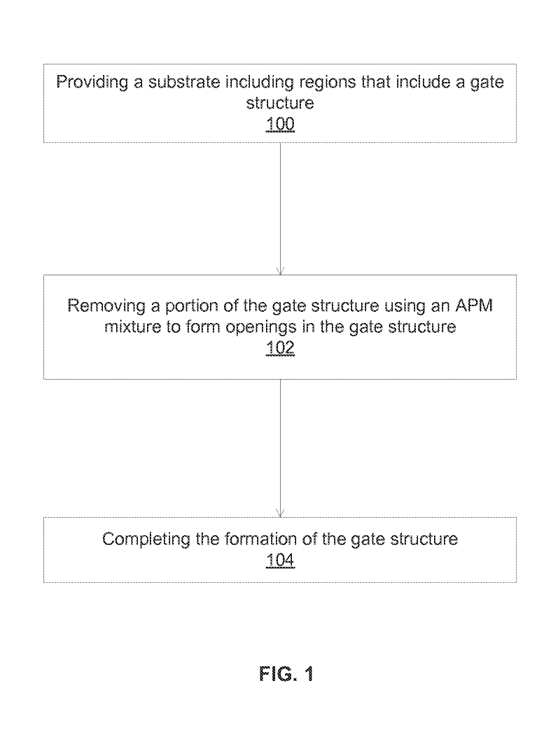

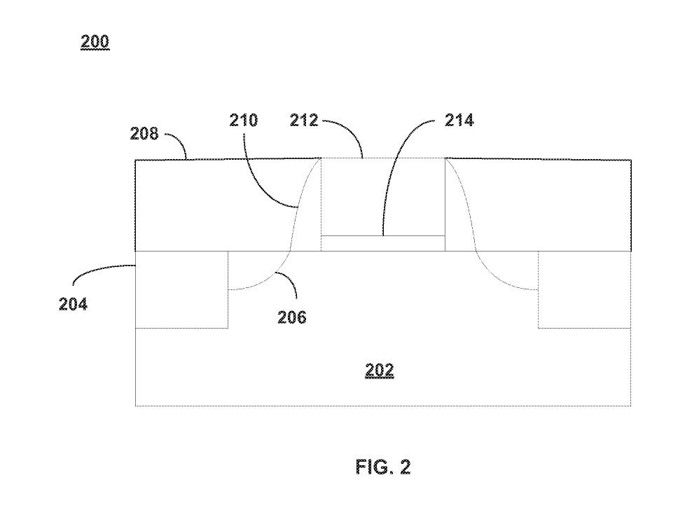

FIG. 1 presents a flow chart describing manufacturing methods according to some embodiments. FIG. 2 illustrates a portion of a semiconductor device formed by the manufacturing methods of FIG. 1. The device may be part of an integrated circuit such as a logic circuit or a memory circuit. Those skilled in the art will understand that the circuit will generally include other device elements such as resistors, capacitors, inductors, fuses, P-channel field effect transistors (PFETs), N-channel field effect transistors (NFETs), metal-oxide-semiconductor field effect transistors (MOSFETs), complimentary metal-oxide-semiconductor field effect transistors (CMOSs), or other suitable device elements. All of these device elements and circuits are manufactured using complex processing sequences consisting of hundreds of steps. Only those steps that are associated with the present disclosure will be described in detail.

In the first step, 100, of the method described in FIG. 1, a substrate is provided that includes regions that include a gate structure. An exemplary region and gate structure, 200, are illustrated in FIG. 2. Those skilled in the art will understand that the substrate has already completed many previous processing steps in the manufacture of the device. The portion of the device illustrated in FIG. 2 includes a portion of the substrate, 202, and isolation regions, 204. The elements identified in FIG. 2 are symmetric, so only the elements on the left side of the figure have been identified. Those skilled in the art will understand that the similar structures on the right side of the figure can be identified by the labels used on the left side. The substrate as described herein is typically silicon, but may also be any one of silicon-germanium, germanium, silicon carbide, gallium arsenide, indium phosphide, etc. The isolation regions, 204, serve to isolate this device from neighboring devices (not shown). The isolation regions are typically silicon oxide, silicon nitride, silicon oxy-nitride, other suitable insulating materials, or combinations thereof. The isolation regions are formed using well known techniques such as LOCal Oxidation of Silicon (LOCOS) or Shallow Trench Isolation (STI).

The portion of the device illustrated in FIG. 2 also includes doped regions, 206, formed in the substrate. The doped regions form the source/drain regions of the device and may be lightly doped or heavily doped. The doped regions may be doped with n-type dopants or p-type dopants.

The portion of the device illustrated in FIG. 2 also includes interlayer dielectric (ILD) layer, 208. Examples of materials suitable for ILD layer, 208, include silicon oxide, silicon nitride, silicon oxy-nitride, low-k dielectric materials, other suitable dielectric materials, or combinations thereof. The ILD layer may be a single layer or may be formed from multiple layers.

The portion of the device illustrated in FIG. 2 also includes a gate structure that includes a dummy gate dielectric layer, 214, a dummy gate layer, 214, and spacers, 210. Those skilled in the art will understand that the gate structure may include other layers (not shown) such as interfacial layers, barrier layers, liner layers, etc. The process used to form the gate structure illustrated in FIG. 2 is well known and include photolithography, etching, deposition, etc. The dummy gate dielectric, 214, and dummy gate layer, 212, protect the underlying substrate during the formation of the spacers, 210, doped regions, 206, ILD layers, 208, and other structures within the device.

At this point in the manufacturing of the device, the dummy gate layer, 212, and the dummy gate dielectric layer, 214, need to be removed so that the high k gate dielectric and the gate electrode materials can be formed. In the next step, 102, of the method of FIG. 1, the portions of the gate structure are removed to form openings in the gate structure (e.g. dummy gate layer, 212, and dummy gate dielectric layer, 214, are removed).

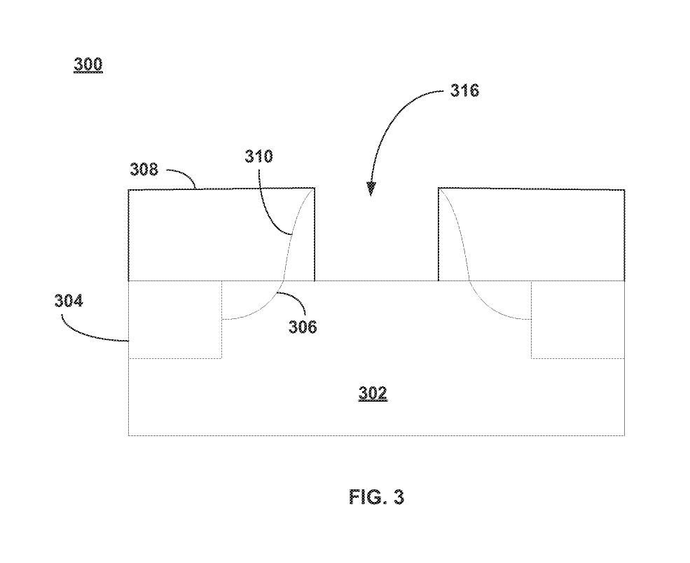

FIG. 3 illustrates an exemplary region and gate structure, 300, after step 102 of FIG. 1. Similar to the portion of the device illustrated in FIG. 2, the portion of the device illustrated in FIG. 3 includes a portion of the substrate, 302, isolation regions, 304, doped regions, 306, formed in the substrate, ILD layer, 308, and spacers, 310. The opening, 316, is formed by the removal of the dummy gate layer, 212, and dummy gate dielectric layer, 214, that were illustrated in FIG. 2.

Traditionally, the dummy gate dielectric layer, 212, is formed from poly-silicon. A common etchant used to remove the poly-silicon is tetramethylammonium hydroxide (TMAH). Although effective at removing poly-silicon, the TMAH process is sensitive to issues such as the pre-doping levels of the poly-silicon. The TMAH is ineffective at removing silicon nitride, so if silicon nitride residues are present, the poly-silicon removal will be incomplete. Additionally, the TMAH etch process is sensitive to the crystal orientation of the poly-silicon. Therefore, the etch may be non-uniform and may result in poly-silicon residues left at the bottom or the sidewall of the opening, 316, illustrated in FIG. 3. One of the criteria for the solution used to remove the poly-silicon is that the etch rate of the poly-silicon must be much greater than the etch rate of silicon oxide so that the sidewalls and the ILD layers are not also removed during the etch process.

In some embodiments, a solution of ammonium hydroxide-hydrogen peroxide-water (APM) is used to remove the dummy gate dielectric layer, 212. The ratio of the constituents of the solution can range from 1:10:20 (ammonium hydroxide : hydrogen peroxide : water) to 1:1:2, such as 1:1:5 or 1:5:20. In some embodiments, the concentration of the ammonium hydroxide is less than or equal to the concentration of water and the ratio of the ammonium hydroxide to water constituents can range from 1:1 to 1:20. The APM solution may be used to remove the poly-silicon at temperatures between 20 C and 80 C, such as between 60 C and 65 C. The time required for the APM solution to remove the poly-silicon can vary between 1 minute and 60 minutes and will depend on parameters such as APM solution concentration, APM solution temperature, poly-silicon thickness, etc. In some embodiments, time required for the APM solution to remove the poly-silicon can vary between 5 minutes and 60 minutes, such as 15 minutes, 25 minutes, or 50 minutes. After the dummy gate layer, 212, is removed, the sample may be rinsed in deionized water.

In some embodiments, the APM solution includes a ratio of ammonium hydroxide:hydrogen peroxide:water of 1:1:5 at a temperature between 60 C and 65 C. In some embodiments, the APM solution includes a ratio of ammonium hydroxide:hydrogen peroxide:water of 1:5:20 at a temperature between 60 C and 65 C.

After the poly-silicon dummy gate layer, 212, is removed, the dummy gate dielectric layer, 214, is removed, typically using a dilute hydrofluoric acid solution, as is well known in the art.

In some embodiments, a thin native oxide forms on top of the dummy gate dielectric layer, 214. As noted previously, the etch rate of silicon oxide in the APM solution is very slow. Therefore, the thin native oxide can be removed by exposing the substrate to a dilute hydrofluoric acid solution prior to the removal of the poly-silicon. This will produce a clean, oxide free poly-silicon surface that can be removed using the APM solution described previously. Alternately, it may be possible to add a small amount of hydrofluoric acid to the APM solution. The hydrofluoric acid constituent would serve to etch the native oxide layer and allow the APM solution to remove the poly-silicon. The concentration of the hydrofluoric acid is maintained at a low level so that it does not result in significant loss of spacer or ILD layer material.

Returning to FIG. 1, the device is ready for the completion of the gate stack and the completion of the manufacture of the circuit in step 104. These steps are well known and will not be described in further detail.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for removing a dummy gate layer from a substrate, the method comprising:
preparing a solution, wherein the solution comprises ammonium hydroxide, hydrogen peroxide, and water,
exposing the substrate to the solution; and
rinsing the substrate, wherein a ratio of ammonium hydroxide:hydrogen peroxide:water is between 1:10:20 and 1:1:2.

2. The method of claim 1 wherein the ratio is 1:10:20.

3. The method of claim 1 wherein the ratio is 1:1:2.

4. The method of claim 1 wherein the ratio is 1:1:5.

5. The method of claim 1 wherein the ratio is 1:5:20.

6. The method of claim 1 wherein the ratio of ammonium hydroxide:water is between 1:1 and 1:20.

7. The method of claim 1 wherein a temperature of the solution is between 20 C and 80 C.

8. The method of claim 1 wherein a temperature of the solution is between 60 C and 65 C.

9. The method of claim 1 wherein a time for the exposing is between 1 minute and 60 minutes.

10. The method of claim 1 wherein a time for the exposing is 15 minutes.

11. The method of claim 1 wherein a time for the exposing is 25 minutes.

12. The method of claim 1 wherein a time for the exposing is 50 minutes.

13. The method of claim 1, further comprising exposing the substrate to a dilute hydrofluoric acid solution before the exposing to the solution.

14. A solution for removing poly-silicon, the solution comprising:
ammonium hydroxide, hydrogen peroxide, and water, wherein a ratio of ammonium hydroxide:hydrogen peroxide:water is between 1:10:20 and 1:1:2.

15. The solution of claim 15 wherein the ratio is 1:10:20.

16. The solution of claim 15 wherein the ratio is 1:1:2.

17. The solution of claim 15 wherein the ratio is 1:1:5.

18. The solution of claim 15 wherein the ratio is 1:5:20.
